(19) United States
(12) Patent Application Publication
(10) Pub. No.: US 2010/0294340 A1
(43) Pub. Date: Nov. 25, 2010

(54) Solar Module with a Frame for Mounting a Solar panel

(76) Inventors: Daniel W. Cunningham, Mt. Airy, MD (US); Kai H.W. Duponte, Warrenville, IL (US); Neil V. Placer, Chattanooga, TN (US); Andy E. Parr, Warrenville, IL (US); Roy Duncan, Warrenville, IL (US); Seigfried Ebner, Warrenville, IL (US)

Correspondence Address: CAROL WILSON;BP AMERICA INC., MAIL CODE 5 EAST, 4101 WINFIELD ROAD, WARRENVILLE, IL, 60555, US

(21) Appl. No.: 12/665,517

(22) PCT Filed: Jun. 12, 2008
(86) PCT No.: PCT/US2008/066641

§ 371 Date: Jul. 19, 2010

Related U.S. Application Data
(60) Provisional application No. 60/944,863, filed on Jun. 19, 2007.

(51) Int. Cl. H01L 31/048; F16M 13/00

(52) U.S. Cl. 136/251; 248/346.5; 248/346.01

(57) ABSTRACT

This invention relates to a frame for mounting a solar panel where a tubular frame member has a generally triangular cross section. The frame member includes a riser element, a span element and a truss element. 5 The frame meets the IEC 61215, Second edition standard for wind and snow loadings without significantly increasing the weight of the solar module compared to conventional frames with an open channel. This invention also relates to an array of solar modules mounted on a structure as well as a method of mounting the frame with a connection channel for slidably accepting an anchor.

This patent application claimed the benefit of U.S. Provisional Patent Application Ser. No. 60/944,863, filed on Jun. 19, 2007.

### BACKGROUND OF THE INVENTION

1. Field of the Invention

This invention relates to solar module frames for mounting solar panels to a structure.

2. Discussion of Related Art

Solar technology seeks to convert energy from the sun into electricity and reduce demands on conventional sources of electricity, such as fossil fuels. The need for renewable energy sources exists in areas with temperate climates as well as areas with winter climates. Solar cells convert sunlight into direct current. Typically, multiple solar cells are positioned between substrate plates or sheets, one of which is transparent to light, and the plates with the solar cells there between formed into solar panels. Such solar panels are usually of a convenient size for handling and for mounting on a roof or other structure, and such panels are typically rectangular in shape.

Solar panels are typically somewhat flexible and are typically set in a supporting frame. Conventional frames that use open channel designs allow bending and/or twisting of parts of the frame when under load, such as from wind or snow accumulation. The wind and the snow loads can damage the solar panel.

Solar modules mounted on the shorter sides of the rectangular shaped solar panel result in a span the length of the solar panel. This arrangement when under load has downward deflection at the center of the span as well as twisting and/or spreading of the frame. The load on the panel may cause the frame to fail when a portion of the solar panel comes out of or disengages the frame due to the twisting or spreading of the frame. This failure also often damages the solar panel requiring replacement of the solar panel.

Structures, such as rooftops, are not always uniform have irregularities which require added installation steps, for example, drilling additional holes in the frame to mount the solar module.

### SUMMARY OF THE INVENTION

One object of this invention is to provide a solar module with a frame for mounting to a structure. There is a need for a frame that can withstand wind and snow loading, for example, according to the IEC 61215, Second edition standard without failing and while not increasing the mass of the solar module over conventional frames. There is also a need for a frame that provides flexibility during installation to allow for irregularities in the structure, such as without drilling additional holes in the frame.

These and other objects of this invention are accomplished with a frame for mounting a solar panel that includes at least one tubular member with a generally triangular cross section taken transverse to a length. The tubular member includes a riser element connecting generally perpendicular to a span element and a truss element extending from the riser element and the span element. The frame includes a flange in combination with the tubular member for receiving at least a portion or a part of the solar panel.

According to certain embodiments of this invention, a solar module with a frame exceeds the strength of the conventional design by at least about twice and more specifically by more than about 2.6 times. The overall strength includes resistance to bending or bowing, particularly at the center and twisting under load which can reduce frame member spreading and failure of the solar module. The improved strength of the frame can exceed requirements of the IEC 61215, Second edition standard for wind and snow loadings.

According to certain embodiments of this invention, the truss element has a curved or arcuate profile or shape. This curved profile may include convex, concave and/or combinations of convex and concave sections or segments with respect to the riser element and the span element. Generally, a convex section can have a knee or a point of inflection, such as closer to the span element than the riser element.

The frame may include other members, such as rectangular shapes. The frame may mount around or along a perimeter of the solar panel. Solar panels may include solar cells, a transparent sheet and a backing sheet. Solar panels, typically, but not necessarily, are rectangular.

The frame members may have any suitable dimension, such as a wall thickness of about 0.5 mm to about 2.5 mm, a height of about 30 mm to about 80 mm and a width of about 10 mm to about 45 mm.

Optionally, the frame may include a sealant along at least a portion of the frame, the flange and/or the solar panel. The sealant keeps out water and may increase the structural rigidity of the solar module.

The span element may form a connection channel along at least a portion of the length of the frame member for receiving or sliding at least a portion of an anchor into the member and attaching it to the structure. The connection channel can provide installation without the need to drill additional holes in and/or through the frame, for example, to compensate for misalignment from an uneven roof. The connection channel may prevent axial rotation of the anchor, such as by holding a head of anchor against a wall or other suitable structure to engage the anchor.

The members of the frame may include at least one attachment boss on or within the frame members for receiving at least one fastener, such as a tapered screw. Attachment bosses help to join or mate frame members, such as at butt joints or lap joints forming corners of the solar panel. Butt joints can be efficiently made during fabrication and installation.

The frame may further include mounting rails receiving the anchor from the connection channel and mounting to the structure. The mounting rails can be arranged in an end mount orientation or an intermediate mount orientation with respect to the solar panel.

This invention also includes an array of solar modules disposed on a structure, for example, arranged in rows and/or columns. Other aspects of this invention include a method of anchoring the solar module that includes providing a solar module with a frame having a connection channel, sliding a portion of at least one anchor into the connection channel and connecting the at least one anchor to the structure.

According to other embodiments of this invention, the frame includes an extruded member for mounting a solar panel to a structure. The extruded member includes a series of linear portions and arc portions arranged to form a generally triangular shape. The extruded member may also include curved fingers forming c-shaped bodies, such as for receiving a part of a fastener. Optionally, the frame may also include a groove along the outside perimeter, such as about 0.5 mm to about 1.5 mm deep and about 5 mm to about 15 mm wide.

### BRIEF DESCRITION OF THE DRAWINGS

The above and other features and objects of this invention are better understood from the following detailed description taken in view of the drawings wherein:

FIG. 1 is a top sectional view of a solar module, according to one embodiment of this invention;

FIG. 2 is a sectional side view of a tubular member, according to one embodiment of this invention;

FIG. 3 is a sectional side view of a rectangular member, according to one embodiment of this invention;

FIG. 4 is a partial sectional side view of a solar module, according to one embodiment of this invention;

FIG. 5 is a top view of an array of solar modules, according to one embodiment of this invention; and

FIG. 6 is a sectional side view of an extruded member, according to one embodiment of this invention.

### DETAILED DESCRIPTION

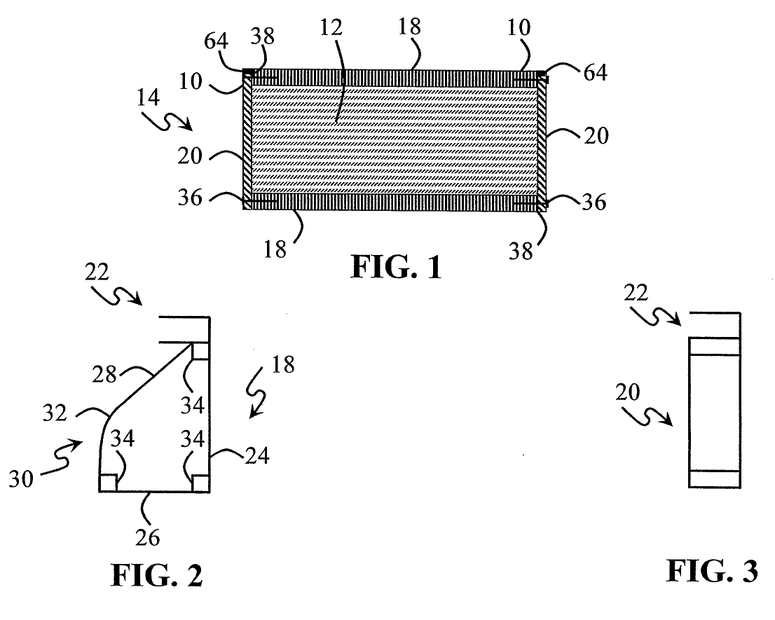

The invention, as shown in FIG. 1, is directed to solar module 14 including frame 10 for holding or mounting solar panel 12. Solar module 14 may include any suitable device or mechanism to convert or transform electromagnetic radiation into electricity. Electromagnetic radiation broadly includes visible light, infrared, ultraviolet and/or any other portion of the electromagnetic spectrum, such as, for example, as emitted from a star.

Electricity broadly includes direct current, alternating current, low voltage, high voltage and/or any other suitable moving of electrons for transmission, storage and/or work. Often, solar modules 14 produce direct current which may be transformed to alternating current, for example, by an inverter.

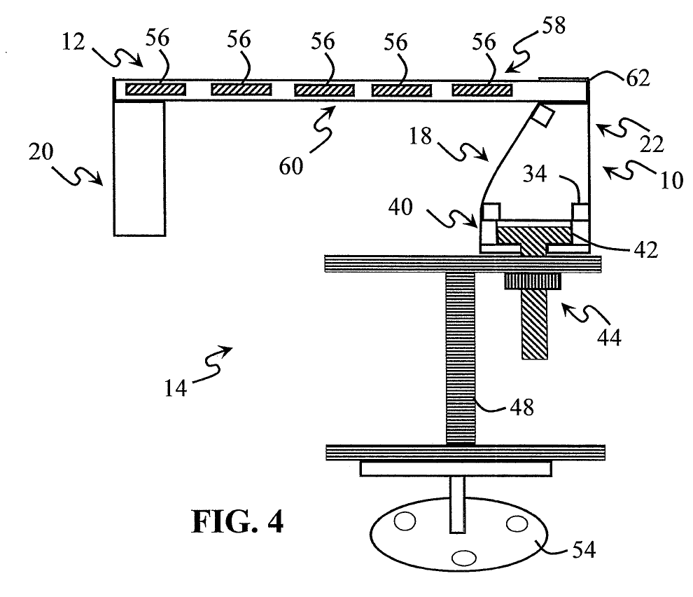

As shown in FIGS. 1 and 4 and according to certain embodiments of this invention, solar module 14 typically includes solar panel 12. Solar panel 12 may include solar cells 56 or photodiodes, transparent sheet 58 or top cover, backing sheet 60 or bottom plate, adhesive, diodes, electrical wiring or harnesses, electrical connectors or plugs, solder joints, batteries and/or any other suitable item or member to make electricity.

Solar panel 12 can be any suitable size and/or shape. Typical dimensions of solar panel 12 may range from fractions of one meter to several meters, such as, for example, a rectangle having a width of about 0.5 m to about 3 m and length of about 1 m to about 5 m. Generally, solar panel 12 can be carried or maneuvered by one person without additional powered lifting equipment. The size of solar panel 12 can be a function of various factors including, but not limited, to material strength, material cost, weather, location, and any other variable impacting design. According to certain embodiments of this invention, solar panel 12 can be about 0.75 m to about 1.1 m by about 1.5 m to about 1.7 m. According to other embodiments of this invention, solar panel 12 can be about 1.7 m by about 1.0 m.

Solar cells 56 may include, without limitation, single-crystal silicon, polycrystal silicon or multicrystal silicon, ribbon silicon, amorphous silicon, cadmium telluride, thin film and/or any other suitable photovoltaic form or element to covert electromagnetic radiation. Typically, any suitable number of solar cells 56 can be arranged within solar panel 12 in series and/or parallel configurations. According to certain embodiments of this invention, solar panel 12 includes sixty solar cells 56. According to other embodiments of this invention, solar panel 12 includes seventy-two solar cells 56.

Transparent sheet 58 includes at least a portion that can pass at least a substantial amount of the desired wavelengths of electromagnetic radiation for capture or conversion by solar cells 56. Materials for transparent sheet 58 may include glass, plastics and/or any other suitable transmissive substance. Generally, transparent sheet 58 can withstand some deflection or bending before cracking or failing. According to certain embodiments of this invention, transparent sheet 58 includes float glass.

Backing sheet 60 may include metals, plastics, laminates, wood members and/or any other suitable materials to at least partially isolate solar panel 12. According to certain embodiments of this invention, backing sheet 60 can be any suitable metallic foil, such as aluminum (Al), and/or polymeric material, for example, polyethylene terephthalate (PET), high density polyethylene (HDPE), polypropylene (PP), Tedlar®, Teflon®, Tefzel® and/or any other suitable fluorinated film. Backing sheet 60 may include laminated or layered structures, such as, for example, Tedlar®/PET/Tedlar® and/or Tedlar®/Al/Tedlar®.

Suitable adhesive materials or glues may be used to join or laminate transparent sheet 58 and/or backing sheet 60 with solar cells 56. Generally, adhesive materials can withstand the working temperature ranges of solar panel 12 and can be at least moisture resistant.

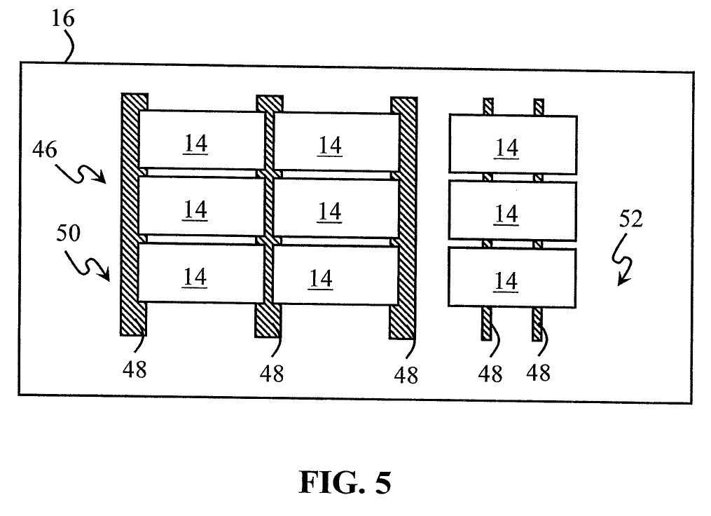

As shown in FIG. 1 and according to certain embodiments of this invention, solar module 14 may include frame 10. Typically, frame 10 holds, mounts, affixes and/or disposes at least a portion of solar panel 12. According to certain embodiments of this invention, frame 10 extends around, bounds and/or traces a perimeter of solar panel 12. Frame 10 generally imparts at least some structural rigidity to solar module 14 and may provide convenient mounting or anchoring points to affix, attach or anchor solar module 14 to structure 16, as shown in FIG. 5. Frame 10 may also raise or elevate solar module 14 from a surface of structure 16, such as to allow air circulation for cooling of solar cells 56 and thereby improve efficiency and/or reliability of solar cells 56.

Frame 10 according to certain embodiments of this invention meets or exceeds, by as much as 20%, the IEC 61215, Second edition standard while having no significant mass increase or change in overall dimensions of solar module 14 compared to conventional frames, not shown.

Compliance with the IEC 61215, Second edition standard allows for solar module 14 to withstand loadings, such as from wind and/or snow accumulation without failure of components since only minimal twisting or bending of frame members occurs. According to certain embodiments of this invention, frame 10 withstands at least 2400 Pa pressure when end mounted, such as from wind loading. According to other embodiments of this invention, frame 10 withstands at least 5400 Pa pressure, such as from snow loading.

Typical failure mechanisms of solar module frames under load or burden include downward deflection or bowing and include twisting or bending of frame members, particularly of the lengthwise members. Twisting of the members may result in a spreading or increasing the frame width until at least a portion solar panel 12 dislodges or pops out of at least a portion of flange 22 of frame 10.

Suitable materials for frame 10 may include aluminum, aluminum alloys, steels, stainless steels, alloys, polymers, reinforced polymer composites and/or any other suitable relatively lightweight and durable substance. Materials can be further treated, such as, for example, painted, galvanized, powder coated, anodized and/or any other suitable technique for improving form and/or function of frame 10. According to certain embodiments of this invention, frame 10 includes 6005-T5, 6061-T6 and/or 6063-T6 aluminum alloys.

Lap joints, butt joints 38, dovetail joints, mortise and tenant joints, miter joints and/or any other suitable union may form frame 10 from the same or different shaped members. According to certain embodiments of this invention and shown in FIG. 1, corners of frame 10 are made or constructed by at least partial butt joints 38, where an end of one member contacts in combination with and/or mates with a side of another member. Butt joints 38 may allow for quick fabrication of frame 10 with minimal labor. Also, butt joints 38 can allow moisture to drain from members to prevent damage by freezing and/or corrosion.

Frame 10 forms corners or angles that may include fasteners 36, such as, for example, screws, bolts, nuts, dowels, washers, rivets, biscuits, cements, glues, epoxies, welds and/or any other suitable mechanical or chemical attaching mechanisms. According to a certain embodiments of this invention, fasteners 36 include at least two machine screws at each corner of frame 10. Fasteners 36 may be counter sunk to minimize protrusions from frame 10, such as to create a smooth perimeter.

Solar panel 12 may be placed in frame 10 with further assistance of calking, glue, adhesive sealant 62 and/or other gasketing material in, on, around and/or between at least a portion of frame 10 and at least a portion of solar panel 12, as shown in FIG. 4 and according to certain embodiments of this invention. Typical adhesive sealants 62 may include butyl polymers, silane polymers, modified silane polymers, silicone polymers, urethane polymers and/or any other suitable relatively water impermeable substance. Adhesive sealant 62 may include water barrier properties, sticking or attaching properties and may also include structural functionality, such as to improve snow and/or wind loading levels of solar module 14.

Typically, frame 10 includes one or more members having a cross section taken transverse to a length. Common manufacturing methods for frame members may include casting, extruding, milling, machining, stamping, pressing, molding and/or any other suitable mass production process. According to certain embodiments of this invention, frame 10 comprises extruded aluminum members.

Frame members can be any size or shape needed to perform the desired functions of frame 10. Typically, but not necessarily, a frame member has a length generally equal to a side of solar panel 12. According to certain embodiments of this invention, frame members have a height of about 30 mm to about 80 mm and a width of about 10 mm to about 45 mm. According to other embodiments of this invention, frame members have a height of about 50 mm and a width of about 26.5 mm.

Frame members may have wall portions with any suitable thickness or dimension. According to certain embodiments of this invention, frame members have a thickness of about 0.5 mm to about 2.5 mm. According to other embodiments of this invention, frame members have a thickness of about 1.3 mm to about 1.9 mm and more specifically about 1.57 mm.

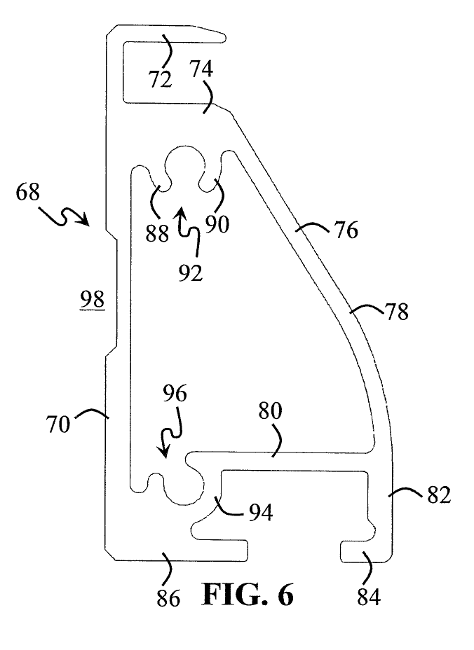

Generally, outside corners of frame members can be rounded, smoothed, radiused, chamfered and/or remain sharp. Similarly, inside corners of members can be rounded, smoothed, radiused, chamfered and/or remain sharp. According to certain embodiments of this invention and as shown in the FIG. 6, sharp corners break, for example, in about 0.40 mm radius or are chamfered, for example, by about 1.0 by about 1.0. Generally, eased corners reduce residual stresses or stress risers created during the manufacturing process. Additionally, eased corners can improve safe handling of materials during installation, operation and/or maintenance, for example, by providing surfaces without sharp edges that could cause lacerations.

According to certain embodiments of this invention, frame members include a cross section with an ergonomic design or shape to further assist gripping and handling of frame members, such as, for example depressions, ridges and/or bulges.

Members of frame 10 may include tubular members 18 and rectangular members 20, as shown in FIGS. 1-4 and according to certain embodiments of this invention. Combinations of different shapes of frame members can facilitate fabrication, installation and/or lower the cost of solar module 14.

As shown in FIG. 2 and according to certain embodiments of this invention, tubular member 18 forms a generally, but not necessarily, closed cross section. Tubular member 18 may include a triangular, a substantially triangular or a generally triangular cross section. As used herein, triangular refers to any relatively three sided shape or configuration. Triangular shapes can offer improved load bearing strength over open channel shapes and/or reduce twisting or torsional movement of tubular member 18. Tubular member 18 generally can impart structural rigidity to frame 10, particularly along a length of solar panel 12 and as shown in FIG. 1.

As shown in FIG. 2 and according to certain embodiments of this invention, tubular member 18 may include at least one riser element 24 that for the sake of convention and description extends in a vertical, a generally vertical and/or a substantially vertical orientation with respect to solar panel 12 when solar panel 12 is attached to frame 10. Riser element 24 can have any of the physical characteristics and/or dimensions described above for members of frame 10. Generally, but not necessarily, riser element 24 forms a linear, a generally linear, a substantially linear and/or a straight segment of the cross section, for example, as a side of a generally triangular shape.

As further shown in FIG. 2 and according to certain embodiments of this invention, tubular member 18 may include at least one span element 26 that for the sake of convention and description extends in a horizontal, a generally horizontal and/or a substantially horizontal orientation with respect to solar panel 12 when solar panel 12 is attached to frame 10. Span element 26 can have any of the physical characteristics and/or dimensions described above for members of frame 10. Generally, but not necessarily, span element 26 forms a linear, a generally linear, a substantially linear and/or a straight segment of the cross section, for example, as a side of a generally triangular shape.

Riser element 24 and span element 26 may connect or meet in any suitable location and at any suitable angle. According to certain embodiments of this invention, riser element 24 and span element 26 may form about a right angle, such as in a perpendicular, a generally perpendicular or a substantially perpendicular connection forming a vertex of a right or a near right triangle.

As further shown in FIG. 2 and according to certain embodiments of this invention, tubular member 18 may include at least one truss element 28 that for the sake of convention and description extends in an angled, a generally angled or a substantially angled orientation with respect to solar panel 12 when solar panel 12 is attached to frame 10. Truss element 28 can have any of the physical characteristics and/or dimensions described above for members of frame 10. Generally, but not necessarily, truss element 28 forms one of a linear, arcuate and/or combinations of straight and curved segments of the cross section, for example, as a side of a generally triangular shape.

Truss element 28 may connect or meet with at least one of riser element 24 and span element 26 at any suitable location and at any suitable angle. According to certain embodiments of this invention, truss element 28 connects with riser element 24 and span element 26 to form a hypotenuse or a hypotenuse-like side of a triangle. Truss element 28 generally imparts structural rigidity to tubular member 18, particularly along a length of tubular member 18.

According to certain embodiments of this invention and as shown in FIG. 2, truss element 28 has a profiled or curved form. The curved form may include a concave shape, convex shape 30 and/or a combination of the concave and convex shapes 30 with respect to riser element 24 and/or span element 26. According to certain embodiments of this invention, truss element 28 forms convex shape 30, as shown in FIG. 2.

Typically, but not necessarily, convex shape 30 includes at least one knee 32 or point of inflection where the shape of the profile changes with respect to one or more discrete or distinct points. Knee 32 can form a bulge or a generally hump-like shape of any suitable size and/or shape. Knee 32 may be located at any position along or with respect to truss element 28. According to certain embodiments of this invention, knee 32 is located or positioned closer or nearer to span element 26 than riser element 24 along truss element 28, such as about the first one fifth to about one half of the distance along truss element 28, starting from where truss element 28 meets span element 26, or such as about one fifth to about two fifths of such distance, or such as about one third of such distance. According to certain embodiments of this invention, knee 32 has a curve of about 10 degrees to about 85 degrees and more specifically about 30 degrees. Typically, knee 32 can have a radius of about 10 mm to about 70 mm, more specifically about 30 mm taken from a point within the tubular member 18.

Tubular member 18 may include one or more extending lips, projections and/or ridges from the cross section of any suitable size and/or shape, for example, to aid in attaching or mounting tubular member 18 to structure 16.

Tubular member 18 may include at least one flange 22 in combination with tubular member 18 for receiving at least a portion of solar panel 12. Flange 22 can form a groove, a lip, a channel, a recess, an edge, a clip and/or any other suitable holding or anchoring structure for solar panel 12. According to certain embodiments of this invention, flange 22 includes a two-sided or a three-sided channel open toward an inside of the frame 10 for mounting at or along a perimeter of solar panel 12.

A depth of flange 22 or top to bottom distance may typically accommodate and/or allow a thickness of solar panel 12 to form, for example, a friction or an interference fit. Alternately, flange 22 may allow for the additional gasketing and/or adhesive sealant 62 as discussed above. Flange 22 can have any suitable width or side to side dimension. According to certain embodiments of this invention, the width of flange 22 is about 5 mm to about 22 mm. According to other embodiments of this invention, the width of flange 22 is about 11 mm, in the horizontal direction of flange 22, such as shown in FIGS. 2-3.

As shown in FIG. 2 and according to certain embodiments of this invention, tubular member 18 may include at least one attachment boss 34. Attachment boss 34 can have any suitable size and/or shape to assist or hold the joint or union of members of frame 10. Attachment boss 34 may run or be along at least a portion of the length of a member of frame 10. According to certain embodiments of this invention, attachment boss 34 receives at least a portion of fastener 36. Attachment boss 34 can have a generally square shape and a width of approximately a diameter of fastener 36, such as, for example, where the threads of fastener 36 interfaces with the walls of attachment boss 34 to form a connection.

Attachment boss 34 may be tapped and/or threaded during fabrication or installation, but generally can be cut by fastener 36, for example, with a tapered screw during assembly. Attachment boss 34 is not limited to straight or square shapes but also may include curved forms. Attachment boss 34 may be located at any location with respect to tubular member 18, particularly along an outside and/or an inside of the cross sectional shape. According to certain embodiments of this invention, at least two attachment bosses 34 are generally located at vertices of the generally triangular shape. Attachment bosses 34 may further improve structural rigidity of frame 10, by reinforcing and/or stiffening tubular member 18, particularly with respect to twisting forces.

Rectangular member 20 may include any suitable size and shape, particularly to compliment and/or mate with tubular member 18. As shown in FIG. 2 and according to certain embodiments of this invention, rectangular member 20 includes a generally rectangular cross section having sides which may further be strengthened by cross members. Cross members may also aid or assist fastener 36 when forming a joint or union. Rectangular member 20 typically, but not necessarily, forms a closed shape.

Rectangular member 20 may have any of the details and/or characteristics discussed above with respect to members of frame 10. A cross section of rectangular member 20 may have a width of about 11 mm and a height of about 50 mm, according to certain embodiments of this invention.

Rectangular member 20 may include at least one flange 22 and/or at least one attachment boss 34 along at least a portion of the length, as discussed above with respect to tubular member 18. Rectangular member 20 may include one or more extending lips, projections and/or ridges from the cross section, for example, to aid in attaching or mounting rectangular member 20 to structure 16. Rectangular member 20 may be used along a width of solar panel 12, such as to form butt joint 38 with tubular member 18, as discussed above.

FIG. 4 shows one embodiment of solar module 14 with tubular member 18 opposite rectangular member 20, such as may occur with solar panels 12 having an odd number of sides.

According to certain embodiments of this invention and as shown in FIG. 4, tubular member 18 may include at least one connection channel 40 along at least a portion of the length and typically, but not necessarily, formed by and/or in span element 26. Generally, at least a portion of an anchor 44 can be slid or moved along connection channel 40. The sliding feature of connection channel 40 can allow flexibility and/or adaptability in mounting and field erection, such as when dealing with an irregular roof on structure 16. Connection channel 40 may save significant labor costs while avoiding drilling additional holes into frame 10. Connection channel 40 may also provide additional structural and/or reinforcing features to members of frame 10, such as to improve twisting resistance or strength.

According to certain embodiments of this invention, connection channel 40 prevents axial rotation of anchor 44 with respect to frame 10. Rotation can be prevented with the shape of connection channel 40, for example, with walls 42 to stop a head of a hex bolt from turning in connection channel 40 and eliminate the need for a wrench to hold the bolt head.

Anchor 44 may include any of the objects or materials described above with respect to fastener 36 and/or may include profiled shapes specially adapted to a particular outline of connection channel 40. According to certain embodiments of this invention, anchor 44 includes stainless steel or any other suitable corrosion resistant material.

This invention further may include one or more mounting rails 48. Mounting rails 48 may include any suitable size and/or shape, such as for example, a box, a channel, a tube, a bar and/or any other suitable attaching form. According to certain embodiments of this invention and as shown in FIG. 4, mounting rail 48 has an I-shape. The I-shape may allow for mounting solar modules 14 next to each other by placing one solar module 14 on each side of the vertical web, such as to accept anchor 44.

Frame 10 of solar module 14 may include one or more end caps 64 or corner pieces, as shown in FIG. 1 and according to certain embodiments of this invention. End caps 64 can be any suitable size and/or shape to prevent moisture and/or debris from accumulating within a portion of a frame member, particularly members forming butt joint 38. End caps 64 may include at least one drain or aperture, for example, to allow condensation to drain from frame 10. End caps 64 can be any suitable material, such as injection molded plastic.

According to certain embodiments of this invention end caps 64 can be pushed or inserted at least partially into both sides of the end frame 10, such as rectangular member 20 at butt joint 38. Typically, end caps 64 lessen or remove sharp corners, hide fasteners 36, and improve aesthetics, such as maintaining groove 98 around solar module 14.

A plurality of or multiple solar panels 14 may be mounted to structure 16 in any suitable number or arrangement to form array 46. Array 46 may include solar modules 14 disposed upon mounting rails 48. Generally, a design of array 46 may seek to maximize a number of solar modules 14 on a structure 16. Solar modules 14 may be abutted next to each other expect for thermal expansion and/or draining tolerances. Alternately, spaces or gaps may remain between solar modules 14, such as to allow personnel access across a roof. Often, but not necessarily, array 46 of solar modules 14 can be mounted in a grid of row and/or columns, such as on a roof.

As shown in FIG. 5 and according to certain embodiments of this invention, solar panels 14 can be arranged in an end mount orientation 50 or configuration with respect to mounting rails 48. End mount orientation 50 can allow a minimal number of mounting rails 48 for a given number of solar panels 14. Typically, but not necessarily, end mount orientation 50 includes placing mounting rails 48 generally along a direction of roof drainage, to prevent accumulation or damming of water.

Solar modules 14 can be placed or mounted lengthwise and/or widthwise across mounting rails 48 and frame 10 to anchor mounting rails 48 with anchor 44. According to certain embodiments of this invention, end mount orientation 50 supports solar modules along the width or the shorter side resulting in a span of the length of solar module 14. End mount orientation 50, for example, may include attaching at tubular member 18 or rectangular member 20 by overlapping lengthwise with mounting rail 48.

Alternately, an intermediate mount 52 or middle mount configuration is also shown in FIG. 5. Intermediate mount 52 can locate or place mounting rails 48 along any suitable interior position of a length or a width of solar module 14, such as, for example about a quarter to about a third of the length from each width edge. Intermediate mount orientation 52 may include more mounting rails 48 for a given number of solar panels 14 than end mount orientation 50.

According to certain embodiments of this invention and as shown in FIG. 4, frame 10 for mounting solar panel 12 may further include at least one brace 54 or foot. Typically, but not necessarily, brace 54 includes adjustment and/or leveling capabilities for placing mounting rail 48 with respect to structure 16. Brace 54 can have any suitable size and/or shape, such as generally T-shaped.

This invention also relates to a method of mounting solar modules 14 with frame 10 having connection channel 40 to structure 16. The method includes sliding, inserting, moving along, and/or engaging at least a portion of anchor 44 into connection channel 40 and tightening, securing, connecting and/or any other suitable action to affix or dispose frame 10 to structure 16.

According to certain embodiments of this invention and as shown in FIG. 6, a side section or side rail of frame 10 may include extruded member 68 for mounting solar panel 12 to structure 16, such as in a lengthwise direction. As shown in FIG. 6, the cross section of extruded member 68 may have generally two open channel structures and a bounded or closed structure as part of a triangular, a substantially triangular or a generally triangular outline.

When referring to the dimensions, shapes, and relative orientations, such as the angles, of the portions of extruded member 68 with reference to FIG. 6, such references to the dimensions, shapes and relative orientations of such portions are with respect to the cross-section, as shown in FIG. 6.

Extruded member 68 may include first linear portion 70 having a length, a first end and a second end. First linear portion 70 may extend vertically, generally vertically and/or substantially vertically.

Extruded member 68 may further include, second linear portion 72 having a length, a first end and a second end where the first end of second linear portion 72 may extend perpendicular, generally perpendicular and/or substantially perpendicular from the second end of first linear portion 70 and may have a length about one eighth to about one half the length of first linear portion 70. According to certain embodiments of this invention, the length of second linear portion 72 may be about one fifth the length of first linear portion 70.

Third linear portion 74 may have a length, a first end and a second end where the first end of third linear portion 74 can extend perpendicular, generally perpendicular and/or substantially perpendicular from first linear portion 70 and in the same direction as second linear portion 72 at a point on first linear portion 70 about a thickness of solar panel 12 below second linear portion 72. Third linear portion 74 may have a length about the same length or different as second linear portion 72.

Extruded member 68 may further include fourth linear portion 76 having a length, a first end and a second end where the first end of fourth linear portion 76 can extend from the second end of third linear portion 74 and may form an acute and/or an obtuse interior angle with respect to first linear portion 70 and third linear portion 74 and fourth linear portion 76 may have a length about one eighth to about three quarters the length of first linear portion 70. According to a certain embodiments of this invention, fourth linear portion 76 has a length about one half the length of first linear portion 70.

First arc portion 78 may have a length, a first end and a second end where the first end of first arc portion 78 can extend from the second end of fourth linear portion 76 and may curve towards first linear portion 70 until the second end of first arc portion 78 is parallel, generally parallel and/or substantially parallel to first linear portion 70. First arc portion 78 may have a length about one tenth to about three quarters of the length of first linear portion 70. According to certain embodiments of this invention, a length of first arc portion 78 is about one fifth the length of first linear portion 70. The length of first arc portion 78, as shown in FIG. 6, encompasses the bend or curve, such as from the second end of fourth linear portion 76 to the first end of fifth linear portion 80.

Fifth linear portion 80 may have a length, a first end and a second end where the first end of fifth linear portion 80 can extend from the second end of first arc portion 78 perpendicular, generally perpendicular and/or substantially perpendicular to first linear portion 70 and the second end of fifth linear portion 80 may join a point on first linear portion 70, not shown in FIG. 6. Fifth linear portion 80 can have a length less than, greater than or equal to a length of first linear portion 70. According to certain embodiments of this invention, a length of fifth linear portion 80 may be about one half the length of first linear portion 70.

Extruded member 68 may further include sixth linear portion 82 having a length, a first end and a second end where the first end of sixth linear portion 82 may extend from the second end of first arc portion 78 parallel, generally parallel and/or substantially parallel to first linear portion 70 and sixth linear portion 82 may have a length about one tenth to about three quarters the length of first linear portion 70. According to certain embodiments of this invention, a length of sixth linear portion 82 may be about one fifth the length of first linear portion 70.

Seventh linear portion 84 can have a length, a first end and a second end where the first end of seventh linear portion 84 may extend from the second end of sixth linear portion 82 perpendicular, generally perpendicular and/or substantially perpendicular to sixth linear portion 82 and toward first linear portion 70. Seventh linear portion 84 can have a length about one twentieth to about one half of the length of first linear portion 70. According to certain embodiments of this invention, the length of seventh linear portion 84 can be about one tenth the length of first linear portion 70.

Eighth linear portion 86 can have a length, a first end and a second end where the first end of eighth linear portion 86 can extend from the first end of first linear portion 70 perpendicular, generally perpendicular or substantially perpendicular to first linear portion 70 and towards seventh linear portion 84 where eighth linear portion 86 can have a length about one tenth to about one half of the length of first linear portion 70. According to certain embodiments of this invention, eighth linear portion 86 can have a length of about one quarter the length of first linear portion 70.

According to certain embodiments and as shown in FIG. 6, extruded member 68 may include first curved finger 88 and second curved finger 90 extending from third linear portion 74 generally toward fifth linear portion 80 and forming first c-shaped body 92. Extruded member 68 may further include third curved finger 94 shortening the length of fifth linear portion 80 at the second end where third curved finger 94 can connect to the first end of first linear portion 70 and the second end of eighth linear portion 86 where third curved finger 94 may form second c-shaped body 98. C-shaped bodies 92, 98 may accept, mate and/or combine with fastener 36 as generally discussed above according to attachment boss 34.

Groove 98 may occur on a generally outward or exterior surface of members of frame 10. Groove 98 may ergonomically assist in a user grabbing or handling frame 10 to reduce slipping. Alternately, groove 98 may be provided for aesthetic, cosmetic, and/or provide manufacturer recognition. Groove 98 may be about 0.5 to about 1.5 mm deep and about 5 mm to about 20 mm wide. According to certain embodiments of this invention, groove 98 is about 1 mm deep and about 12 mm wide.

According to certain embodiments of this invention, solar module 14 exceeds the strength of the conventional design by at least twice and more specifically by more than about 2.6 times. This strength includes resistance to bending or bowing, particularly at the center of an end mount orientation 50. The torsional movement or twisting under load can be improved to reduce possible spreading of frame 10 and failure of solar module 14. The improved strength of frame 10 according to certain embodiments of this invention exceeds the IEC 61215, Second edition standard for wind and snow loadings.

### EXAMPLES

Frame 10, according to certain embodiments of this invention, with extruded member 68, as shown in FIG. 6, was subjected to physical testing along with a conventional solar module frame having an open channel design. The results for wind loading are summarized in Table 1 and show significantly increased performance by frame 10 versus the conventional design.

TABLE 1

| Pressure | Vertical Deflection | Lateral Width |
|---|---|---|
| 2400 Pa | (mm) | Increase (mm) |
| Conventional | −16.0 | 11.5 |
| Improvement | −13.5 | 0.5 |

Similarly, the overall solar module 14 strength according to certain embodiments of this invention was tested to successfully withstand loads of at least 6240 Pa and thereby exceeded the IEC 61215, Second edition standard of 5400 Pa. The testing of module 14, according to certain embodiments of this invention with extruded member 68 as shown in FIG. 6, had an at least about 2.6 times increase in overall module strength compared to the conventional solar module having an open channel frame design.

While in the foregoing specification this invention has been described in relation to certain preferred embodiments, and many details are set forth for purpose of illustration, it will be apparent to those skilled in the art that this invention is susceptible to additional embodiments and that certain of the details described in this specification and in the claims can be varied considerably without departing from the basic principles of this invention.

U.S. Provisional Patent Application Ser. No. 60/944,863, filed on Jun. 19, 2007, is incorporated herein by reference in its entirety.

What is claimed is:

1. A frame for mounting a solar panel, the frame comprising:
at least one tubular member, the tubular member having a length and a generally triangular cross section transverse to the length, the tubular member comprising a riser element connecting generally perpendicular to a span element and an at least partially arcuate truss element extending from the riser element and the span element; and
a flange in combination with the tubular member for receiving at least a portion of the solar panel.

2. The frame for mounting a solar panel according to claim 1, wherein at least a part of the truss element has a convex shape with respect to the riser element and the span element.

3. The frame for mounting a solar panel according to claim 2, wherein the convex shape includes a knee positioned closer to the span element than the riser element.

4. The frame for mounting a solar panel according to claim 1, wherein the tubular member includes at least one attachment boss disposed within the tubular member for receiving at least one fastener.

5. The frame for mounting a solar panel according to claim 4, further comprising at least one rectangular member in combination with and mating with the tubular member.

6. The frame for mounting a solar panel according to claim 5, wherein the rectangular member and the tubular member form a butt joint attached by at least one fastener and the at least one attachment boss.

7. The frame for mounting a solar panel according to claim 1, further comprising a connection channel formed in the span element along at least a part of the length of the tubular member to receive a portion of an anchor for mounting the frame to a structure.

8. The frame for mounting a solar panel according to claim 7, wherein the connection channel slidably accepts an anchor for mounting the frame to the structure and the connection channel prevents axial rotation of the anchor with respect to the frame.

9. The frame for mounting a solar panel according to claim 8, further comprising:
mounting rails receiving the anchor from the connection channel and mounting to the structure in an end mount orientation with respect to the solar panel.

10. A solar module for anchoring to a structure, the solar module comprising:
a solar panel including at least one solar cell disposed between a transparent sheet and a backing sheet;
a frame for mounting the solar panel including at least one tubular member, the tubular member having a length and a generally triangular cross section transverse to the length, the tubular member comprising a riser element connecting generally perpendicular to a span element and an at least partially arcuate truss element extending from the riser element and the span element;
a flange in combination with the tubular member for receiving at least a portion of the solar panel;
a connection channel formed in the span element along at least a part of the length of the tubular member to receive a portion of an anchor for joining the frame to the structure.

11. The solar module according to claim 10, wherein the tubular member includes at least one attachment boss.

12. The solar module according to claim 10, wherein the riser element, the span element and the truss element having a thickness of about 0.5 mm to about 2.5 mm.

13. The solar module according to claim 10, wherein:
the tubular member having a height of about 30 mm to about 80 mm; and
the tubular member having a width of about 10 mm to about 45 mm.

14. The solar module according to claim 10, further comprising:
at least one rectangular member in combination with and mating with the at least one tubular member.

15. The solar module according to claim 10, wherein:
the solar panel having a perimeter edge and a rectangular shape with a length greater than a width;
tubular members disposed along the length of the solar panel and rectangular members disposed along the width of the solar panel to bound the perimeter edge of the solar panel; and
a sealant applied to at least a portion of the perimeter edge and the frame.

16. An array of the solar modules according to claim 10, anchoring on a structure comprising:
a plurality of solar modules disposed on a structure in an end mount orientation.

17. A method of anchoring the solar module according to claim 10 to a structure, the method comprising:
providing a solar module including a frame with a connection channel;
sliding a portion of at least one anchor into the connection channel; and
connecting the at least one anchor to the structure.

18. An extruded member for mounting a solar panel to a structure, the extruded member comprising:
a first linear portion having a length, a first end and a second end, the first linear portion extending generally vertically;
a second linear portion having a length, a first end and a second end, the first end of the second linear portion extending generally perpendicular from the second end of the first linear portion and having a length about one eighth to about half the length of the first linear portion;
a third linear portion having a length, a first end and a second end, the first end of the third linear portion extending generally perpendicular from the first linear portion and in the same direction as the second linear portion at point on the first linear portion about a thickness of a solar panel below the second linear portion, the third linear portion having a length about the same length as the second linear portion;
a fourth linear portion having a length, a first end and a second end, the first end of the fourth linear portion extending from the second end of the third linear portion and forming an acute interior angle with respect to the first linear portion and the third linear portion, the fourth linear portion having a length about one eighth to about three quarters the length of the first linear portion;
a first arc portion having a length, a first end and a second end, the first end of the first arc portion extending from the second end of the fourth linear portion and curving towards the first linear portion until the second end of the first arc portion is generally parallel to the first linear portion, the first arc portion having a length about one tenth to about three quarters the length of the first linear portion;
a fifth linear portion having a length, a first end and a second end, the first end of the fifth linear portion extending from the second end of the first arc portion generally perpendicular to the first linear portion and the second end of the fifth linear portion joining a point on the first linear portion, the fifth linear portion having a length greater than or less than about the length of the first linear portion;
a sixth linear portion having a length, a first end and a second end, the first end of the sixth linear portion extending from the second end of the first arc portion generally parallel to the first linear portion, the sixth linear portion having a about one tenth to about three quarters the length of the first linear portion;
a seventh linear portion having a length, a first end and a second end, the first end of the seventh linear portion extending from the second end of the sixth linear portion generally perpendicular to the sixth linear portion and toward the first linear portion; the seventh linear portion having a length about one twentieth to about one half the length of the first linear portion; and
an eighth linear portion having a length, a first end and a second end, the first end of the eighth linear portion extending from the first end of the first linear portion generally perpendicular to the first linear portion and towards the seventh linear portion, the eighth linear portion having a length about one tenth to about one half the length of the first linear portion.

19. The generally triangular tubular member for a solar frame to mount a solar panel to a structure according to claim 18, further comprising:
a first curved finger and a second curved finger extending from the third linear portion toward the fifth linear portion forming a first c-shaped body; and
a third curved finger shortening the length of the fifth linear portion at the second end, the third curved finger connecting to the first end of the first linear portion and the second end of the eighth linear portion, the third curved finger forming a second c-shaped body.

20. The generally triangular tubular member for a solar frame to mount a solar panel to a structure according to claim 18, wherein:
the first linear portion forms a groove on an exterior surface of the frame about 0.5 to about 1.5 mm deep and about 5 mm to about 15 mm wide.
